(19) United States
(12) Patent Application Publication
(10) Pub. No.: US 2024/0321964 A1
(43) Pub. Date: Sep. 26, 2024

(54) TRENCH SEMICONDUCTOR POWER DEVICE AND LAYOUT THEREOF

(71) Applicant: Hangzhou Silicon-Magic Semiconductor Technology Co., Ltd, Hangzhou City (CN)

(72) Inventors: Jian Liu, Torrance, CA (US); Jinyong Cai, Hangzhou City (CN)

(21) Appl. No.: 18/542,211

(22) Filed: Dec. 15, 2023

(30) Foreign Application Priority Data
Mar. 20, 2023 (CN) 202310281669.1
May 19, 2023 (CN) 202310582449.2

(51) Int. Cl. H01L 29/06; H01L 29/423; H01L 29/78

(52) U.S. Cl. CPC H01L 29/0696; H01L 29/4236; H01L 29/7813

(57) ABSTRACT

A trench semiconductor power device includes: a substrate of a first dopant type; an epitaxial layer of the first dopant type; a source trench structure that is inside the epitaxial layer and is annular; a gate trench structure that is inside the epitaxial layer and is annular; a bridge trench structure inside the epitaxial layer; a base region of a second dopant type between the source trench structure and the adjacent gate trench structure; a source region of the first dopant type in the base region; a gate metal layer, connected to the gate trench structure; and a source metal layer, connected to the source trench structure and the source region. The bridge trench structure is connected between two adjacent gate trench structures, passes through the source trench structure between two adjacent gate trench structures, and cuts the source trench structure into a plurality of arc-shaped trench sections.

### TECHNICAL FIELD

The present disclosure relates to the technical field of semiconductors, and in particular, to a trench semiconductor power device and layout thereof.

### BACKGROUND

The shielded gate trench power device (SGT MOSFET) is a new type of power semiconductor device that has the advantages of low conduction losses of traditional deep trench MOSFETs and lower switching losses. The shielded gate trench power device (SGT MOSFET) is used in motor drive systems, inverter systems and power management systems in the fields of new energy electric vehicles, new photovoltaic power generation, energy-saving home appliances, etc., which is a significant switching component.

The shielded gate trench power device (SGT MOSFET) has a deep trench structure in the drift zone, which is a main difference from the traditional power devices. The deep trench structure uses a transverse electric field to deplete the drift zone, such that the drift zone (the area between deep trenches) can use higher doping concentrations to reduce on-resistance and further to break through the silicon limit performance of traditional power devices.

With the development of shielded gate trench power device (SGT MOSFET) technology, the separated shielded gate trench provides greater design flexibility. Due to the relatively larger size of the separated shield gate structure, there exists a need to increase the cell density of the device through layout.

### SUMMARY

The present application provides a trench semiconductor power device and layout thereof to increase cell density of the device.

According to one or more embodiments of the present disclosure, a trench semiconductor power device comprises: a substrate of a first dopant type; an epitaxial layer of a first dopant type, located on a first surface of the substrate; a source trench structure, located inside the epitaxial layer and constructed to be annular; a gate trench structure, located inside the epitaxial layer and constructed to be annular, wherein the source trench structure and the gate trench structure are arranged spaced apart from each other and alternately; a bridge trench structure, located inside the epitaxial layer, wherein the bridge trench structure is connected between two adjacent gate trench structures, passes through the source trench structure between two adjacent gate trench structures, and cuts the source trench structure into a plurality of arc-shaped source trench sections, and an end of each of the arc-shaped source trench sections is spaced apart from the bridge trench structure; a base region of a second dopant type, arranged between the source trench structure and the gate trench structure adjacent to each other, wherein the second dopant type is opposite to the first dopant type; a source region of the first dopant type, arranged in the base region; a gate metal layer, connected to the gate trench structure; and a source metal layer, connected to the source trench structure and the source region, wherein the source metal layer and the gate metal layer are spaced apart from each other.

According to one or more embodiments of the present disclosure, a trench semiconductor power device layout, comprises: a source trench structure, constructed to be annular; a gate trench structure, constructed to be annular, wherein the source trench structure and the gate trench structure are arranged spaced apart from each other and alternately; and a bridge trench structure, wherein the bridge trench structure is connected between two adjacent gate trench structures, passes through the source trench structure between two adjacent gate trench structures, and cuts the source trench structure into a plurality of arc-shaped source trench sections, and an end of each of the arc-shaped source trench sections is spaced apart from the bridge trench structure.

### BRIEF DESCRIPTION OF THE DRAWINGS

The foregoing and other objects, features, and advantages of the present application will become more apparent from the following description of embodiments with reference to the accompanying drawings.

FIG. 1 shows a schematic diagram of the layout structure of a trench semiconductor power device according to one or more embodiments of the present disclosure.

FIG. 2 shows a schematic diagram of a cross-sectional structure at A-A in FIG. 1.

FIG. 3 shows an enlarged view of B in FIG. 2.

FIG. 4 shows a schematic diagram of a distribution of a first trench, a second trench, and a third trench according to one or more embodiments of the present disclosure.

FIG. 5 shows a schematic structural diagram of a trench semiconductor power device according to one or more embodiments of the present disclosure.

FIG. 6 shows an enlarged view of C in FIG. 5.

FIG. 7 shows a schematic diagram of the layout structure of a trench semiconductor power device according to one or more embodiments of the present disclosure.

FIG. 8 shows an enlarged view of D in FIG. 7.

### DETAILED DESCRIPTION

The present disclosure will be described in more detail below with reference to the accompanying drawings. In each accompanying drawing, the same elements are denoted by the similar reference numerals. For the sake of clarity, each part in the accompanying drawings is not drawn to scale. In addition, some well-known parts may not be shown. For the sake of simplicity, a semiconductor structure obtained after several steps may be described in a drawing.

It should be understood that during the description of the structure of a device, when a layer or region is referred to as being located “on” or “above” another layer or region, it may be directly located on another layer or region, or other layers or regions are also included between it and another layer or region. Moreover, if the device is turned over, the layer or region will be located “under” or “below” another layer or region.

In order to describe the situation of being directly located on another layer or region, the expression “directly on . . . ” or “on and adjacent to . . . ” will be adopted herein.

The specific implementation of the present disclosure will be further described in detail below with reference to the accompanying drawings and the embodiments.

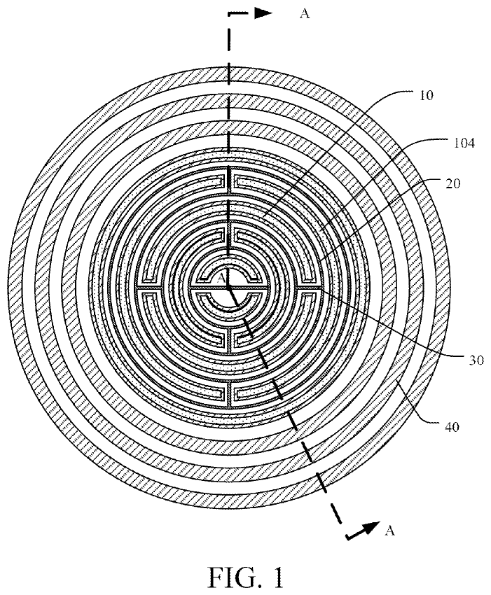

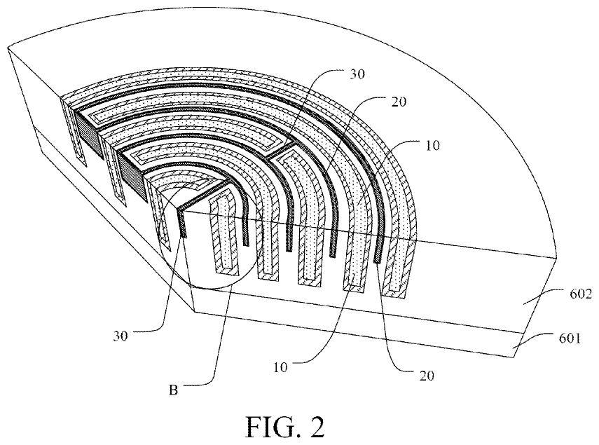

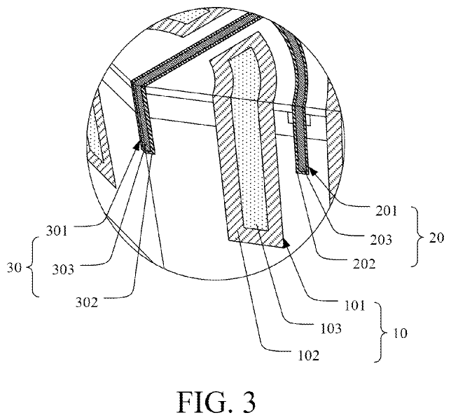

FIG. 1 shows a schematic diagram of the layout structure of a trench semiconductor power device according to one or more embodiments of the present disclosure. FIG. 2 shows a schematic diagram of a cross-sectional structure at A-A in FIG. 1. FIG. 3 shows an enlarged view of B in FIG. 2. In one or more embodiments, a first dopant type is one of an N type or a P type, and a second dopant type is the other of the N type and the P type. An N-type semiconductor layer may be formed by implanting an N-type dopant, such as P and As, into a semiconductor layer. A P-type semiconductor layer may be formed by doping a P-type dopant, such as B, into the semiconductor layer.

As shown in FIG. 1, FIG. 2, and FIG. 3, a trench semiconductor power device provided in this embodiment includes a substrate 601, an epitaxial layer 602 located on a first surface of the substrate 601. A source trench structure 10, a gate trench structure 20, and a bridge trench structure 30 are located in the epitaxial layer 602.

The substrate 601 may be a silicon substrate, a strain silicon substrate, a germanium substrate, a germanium-silicon substrate, a silicon carbide substrate, or III-V group chemical compound substrate, etc., and are not limited to the examples listed above. The substrate 601, as a drain region of the device, has a first type of doping. In one or more embodiments, the substrate 601 is heavy N-type doping. The epitaxial layer 602 may be formed in the substrate 601 by doping, or may be formed on the substrate 601 by manners such as epitaxy. The epitaxial layer 602, as a drift region of the device, has the first dopant type. In one or more embodiments, the epitaxial layer 602 is light N-type dopant relative to the substrate 601.

As shown in FIG. 1, a source trench structure 10 and a gate trench structure 20 are located within the epitaxial layer 602. Layout structures of the source trench structure 10 and the gate trench structure 20 are constructed to be annular, and the source trench structure 10 and the gate trench structure 20 are arranged spaced apart from each other and alternately.

The bridge trench structure 30 is located within the epitaxial layer 602, and is connected between two adjacent gate trench structures 20. The bridge trench structure 30 passes through the source trench structure 10 between two adjacent gate trench structures 20, and cuts the source trench structure 10 into a plurality of arc-shaped source trench sections 104, and an end of each of the arc-shaped source trench sections 104 is spaced apart from the bridge trench structure 30.

The gate trench structures 20 are arranged in an annular shape, and two adjacent gate trench structures 20 are connected by the bridge trench structure 30. The arrangement can increase a density of the gate trench structures 20 per unit area, that is, increase a channel density in a period of the device is turned on, thereby reducing a specific on-resistance of the device.

Two or more bridge trench structures 30 are arranged between two adjacent gate trench structures 20, and the bridge trench structures 30 in an inner ring and an outer ring adjacent to each other are staggered with respect to each other. According to one or more embodiments shown in FIG. 1, two bridge trench structures 30 are arranged between two adjacent gate trench structures 20, and the bridge trench structures 30 in an inner ring and an outer ring adjacent to each other are staggered with respect to each other by 90 degrees. This arrangement can cause distribution of the arc-shaped source trench section 104 more uniform, so that when the device is subsequently subjected to a voltage, depletion of a drift region 602 close to the arc-shaped source trench section 104 is more uniform, thereby improving a voltage endurance capability of the trench semiconductor power device.

The bridge trench structure 30 is further provided in the gate trench structure 20 of an innermost ring, and the bridge trench structure 30 extends in a diameter direction of the gate trench structure 20 of the innermost ring and both ends thereof are connected to the gate trench structure 20 of the innermost ring. Meanwhile, the bridge trench structure 30 cuts the source trench structure 10 of the innermost ring into the arc-shaped source trench section 104.

With an increase of the density of the gate trench structure 20, a channel density of the device can be effectively increased and the specific on-resistance can be reduced, but the voltage endurance capability of the device may be insufficient. In order to ensure the voltage endurance capability of the device, one or more embodiments of the present disclosure provide an annular source trench structure 10 to cooperate with the gate trench structure 20 on an annular side to ensure the voltage endurance capability of the device, and the depletion of the drift region 602 close to the arc-shaped source trench section 104 is more uniform. Therefore, while improving the specific on-resistance of the device, the voltage endurance capability of the device is greatly improved.

In one or more embodiments, as shown in FIG. 2 and FIG. 3, the source trench structure 10 includes a first trench 101, a first dielectric layer 102 and a first conductor 103 arranged in the first trench 101. The first trench 101 extends from a surface of the epitaxial layer 602 away from the substrate 601 toward an interior of the epitaxial layer 602, the first dielectric layer 102 covers sidewalls and a bottom of the first trench 101, and the first conductor 103 is isolated from the sidewalls and the bottom of the first trench 101 through the first dielectric layer 102.

The gate trench structure 20 includes a second trench 201, a second dielectric layer 202 and a second conductor 203 arranged in the second trench 201. The second trench 201 extends from a surface of the epitaxial layer 602 away from the substrate 601 toward an interior of the epitaxial layer 602, the second dielectric layer 202 covers sidewalls and a bottom of the second trench 201, and the second conductor 203 is isolated from the sidewalls and the bottom of the second trench 201 through the second dielectric layer 202.

The bridge trench structure 30 includes a third trench 301, a third dielectric layer 302 and a third conductor 303 arranged in the third trench 301. The third trench 301 respectively extends from a surface of the epitaxial layer 602 away from the substrate 601 toward an interior of the epitaxial layer 602, the third dielectric layer 302 covers sidewalls and a bottom of the third trench 301, and the third conductor 303 is isolated from the sidewalls and the bottom of the third trench 301 through the third dielectric layer 302.

The first dielectric layer 102, the second dielectric layer 202, and the third dielectric layer 302 may be composed of SiO₂ or a material having a dielectric constant greater than SiO₂, including, for example, oxides, nitrides, nitrogen oxides, silicates, aluminates, and titanates salt. In addition, the first dielectric layer 102, the second dielectric layer 202, and the third dielectric layer 302 may be formed not only of a material known to a person skilled in the art, but also of a material for a dielectric developed in the future. The first conductor 103, the second conductor 203 and the third conductor 303 may be formed by a variety of materials capable of conducting electricity, such as a metal layer, a doped polysilicon layer, a laminated grid conductor including a metal layer and the doped polysilicon layer, or other conductive materials, such as TaC, TiN, TaSiN, HfSiN, TiSiN, TiCN, TaAlC, TiAlN, TaN, PtSix, Ni3Si, Pt, Ru, W, and a combination of various conductive materials.

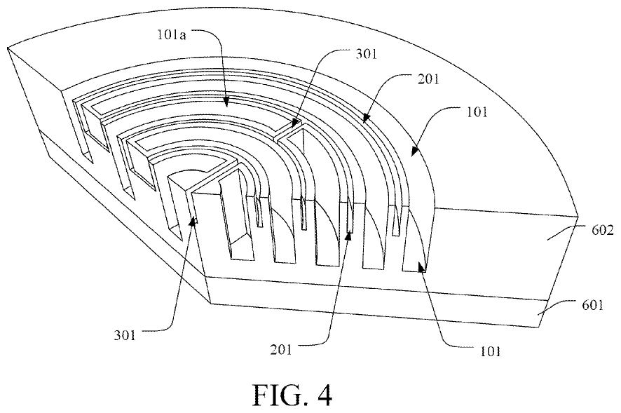

FIG. 4 shows a schematic diagram of a distribution of a first trench, a second trench, and a third trench according to one or more embodiments of the present disclosure. As shown in FIG. 4, the first trench 101 and the second trench 201 are constructed to be annular, the first trench 101 and the second trench 201 are spaced apart from each other, and the first trench 101 and the second trench 201 are alternately arranged from a center of the epitaxial layer 602 toward an edge direction of the epitaxial layer 602. The third trench 301 is located between two adjacent second trenches 201 and is respectively in communication with the two adjacent second trenches 201. The third conductor 303 located in the third trench 301 and the second conductor 203 located in the two adjacent second trenches 201 are connected. The third trench 301 passes through the first trench 101 between the two adjacent second trenches 201, and cuts the first trench 101 into a plurality of first trench arc sections 101a, and an end of each of the first trench arc sections 101a and the third trench 301 are isolated by the epitaxial layer.

In one or more embodiments, the second trench 201 has a same depth as the third trench 301. A depth of the second trench 201 and a depth of the third trench 301 is less than or equal to one-third of a depth of the first trench 101. In one or more embodiments, the depths of the second trench 201 and the third trench 301 are set to be shallow, and the first trench 101 is set to be deep. On the one hand, a depth of the source trench structure 10 is increased, and on the other hand, a spatial distance between the source trench structure 10 and the gate trench structure 20 and the bridge trench structure 30 is increased. Such a design may alleviate electric field concentration that occurs when the device is subjected to a voltage, thereby improving the voltage endurance capability of the device.

In one or more embodiments, the second dielectric layer 202 has a same thickness as the third dielectric layer 302. The thicknesses of the first dielectric layer 102 are respectively greater than the thicknesses of the second dielectric layer 202 and the third dielectric layer 302. In one or more embodiments, the first dielectric layer 102 on the sidewall of the source trench structure 10 is set to be thick, so that the breakdown voltage can be increased. At the same time, the thickness of the second dielectric layer 202 of the gate trench structure 20 and the third dielectric layer 302 of the bridge trench structure 30 are set to be small, which can improve the control capability of the device on the channel.

As shown in FIG. 3, in one or more embodiments, a thickness of a second dielectric layer 202 located at a bottom of a second trench 201 is greater than a thickness of a second dielectric layer 202 located at a sidewall of the second trench 201, and a thickness of a third dielectric layer 302 located at a bottom of a third trench 301 is greater than a thickness of a third dielectric layer 302 located at a sidewall of the third trench 301. The formation of the channel is mainly concentrated on the sidewall of the second trench 201 and the sidewall of the third trench 301. Therefore, in one or more embodiments, the thickness of the second dielectric layer 202 on the sidewall of the second trench 201 and the third dielectric layer 302 on the sidewall of the third trench 301 is set to be small, which can facilitate the formation of the channel and improve the control capability of the device on the channel. The thickness of the second dielectric layer 202 at the bottom of the second trench 201 and the third dielectric layer 302 at the bottom of the third trench 301 is set to large, which can effectively improve the breakdown resistance of the bottom of the trench.

In one or more embodiments, the depth of the second trench 201 and the depth of the third trench 301 are 1 micron˜2 microns, and the depth of the first trench 101 is 3 microns˜6 microns. The thickness of the first dielectric layer 102 located at the sidewall and bottom of the first trench 101 is 0.4 microns˜0.6 microns. The thickness of the second dielectric layer 202 located at the bottom of the second trench 201 and the thickness of the third dielectric layer 302 located at the bottom of the third trench 301 are 500 angstroms˜800 angstroms. The thickness of the second dielectric layer 202 located at the sidewall of the second trench 201 and the thickness of the third dielectric layer 302 located at the sidewall of the third trench 301 are 0.1 microns˜0.2 microns. A spacing between the adjacent the source trench structure 10 and the gate trench structure 20 is greater than or equal to 0.3 microns. The width of the gate trench structure 20 and the width of the bridge trench structure 30 are 0.2 microns˜0.5 microns, and the width of the source trench structure 10 is 1 micron˜1.5 microns.

In one or more embodiments, a use voltage of the trench semiconductor power device is 100 V, a depth of the gate trench structure 20 and a depth of the bridge trench structure 30 are 1.5 microns, and a depth of the source trench structure 10 is 5 microns. A thickness of the first dielectric layer 102 on the sidewalls and bottom of the source trench structure 10 is 0.5 microns. A thickness of the second dielectric layer 202 at the bottom of the second trench 201 and a thickness of the third dielectric layer 302 at the bottom of the third trench 301 are 600 angstroms. A thickness of the second dielectric layer 202 located at the sidewall of the second trench 201 and a thickness of the third dielectric layer 302 located at the sidewall of the third trench 301 are 0.15 microns. A spacing between the adjacent source trench structure 10 and the gate trench structure 20 is 0.3 microns. A width of the gate trench structure 20 and a width of the bridge trench structure 30 are 0.25 microns, and a width of the source trench structure 10 is 1.2 microns.

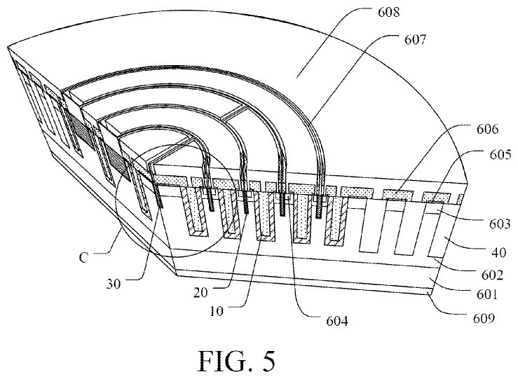

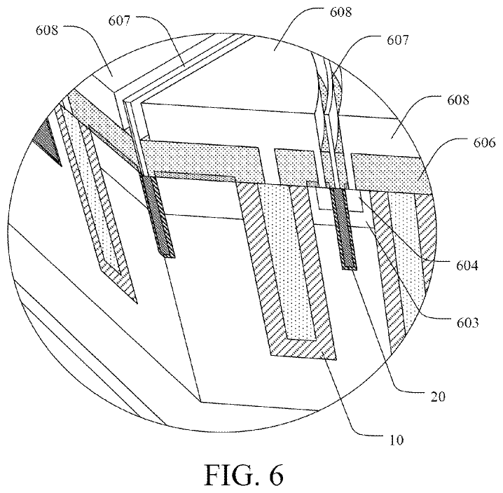

FIG. 5 shows a schematic structural diagram of a trench semiconductor power device according to one or more embodiments of the present disclosure. FIG. 6 is an enlarged view of C in FIG. 5. As shown in FIG. 1 and FIG. 5, the trench semiconductor power device further includes a plurality of peripheral trench structures 40. Each of the peripheral trench structures 40 is located in the epitaxial layer 602, and the peripheral trench structure 40 is constructed to be annular and surrounds the source trench structure 10, the gate trench structure 20, and the bridge trench structure 30. The peripheral trench structure 40 can fully deplete the drift region 602 around the device when the device is subjected to a voltage, thereby further improving the voltage endurance capability of the device.

The trench semiconductor power device includes a base region 603 of the second type of doping and a source region 604 of the first type of doping. The base region 603 is located in the epitaxial layer 602 and is adjacent to the source trench structure 10, the gate trench structure 20, the bridge trench structure 30, and the peripheral trench structure 40, respectively. The source region 604 is arranged in the base region 603 and is adjacent to the source trench structure 20.

The trench semiconductor power device includes a protective layer 605 and a dielectric layer 606. The protective layer 605 is located on a surface of the epitaxial layer 602, exposing the source trench structure 10, the gate trench structure 20, the bridge trench structure 30, and the peripheral trench structure 40. The dielectric layer 606 covers a surface of the protective layer 605 and surfaces of the source trench structure 10, the gate trench structure 20, the bridge trench structure 30, and the peripheral trench structure 40.

The trench semiconductor power device includes a gate metal layer 607 and a source metal layer 608. The gate metal layer 607 is located on a surface of the dielectric layer 606, and the gate metal layer 607 contacts the second conductor 203 of the gate trench structure 20 through the dielectric layer 606. The source metal layer 608 is located on a surface of the dielectric layer 606. The source metal layer 608 passes through the dielectric layer 606 and contacts the first conductor 103 of the source trench structure 10, passes through the dielectric layer 606 and the protective layer 605 and contacts the source region 604, and passes through the dielectric layer 606 and the protective layer 605 and contacts the peripheral trench structure 40. The source metal layer 608 and gate metal layer 607 are spaced apart from each other.

The trench semiconductor power device includes a drain metal layer 609. The drain metal layer 609 is arranged on a second surface of the substrate 601 and contacts the substrate 601, and a first surface of the substrate 601 is opposite to a second surface of the substrate 601.

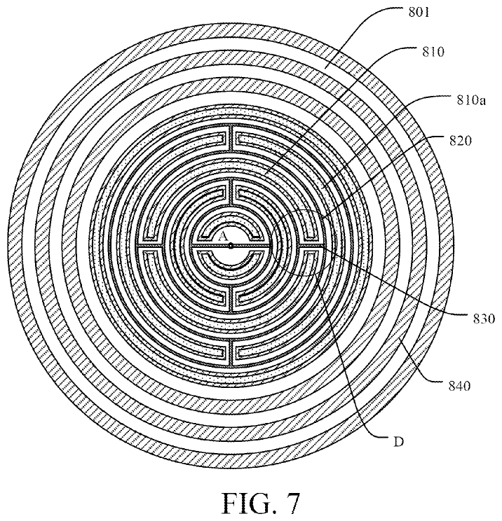

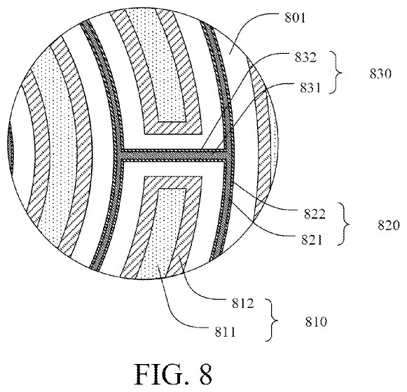

FIG. 7 shows a schematic structural diagram of a trench semiconductor power device layout according to one or more embodiments of the present disclosure. FIG. 8 shows an enlarged view of D in FIG. 7. As shown in FIG. 7 and FIG. 8, the trench semiconductor power device layout 80 includes an epitaxial layer 801 and a source trench structure 810, a gate trench structure 820, and a bridge trench structure 830 arranged inside the epitaxial layer 801.

The source trench structure 810 and the gate trench structure 820 are constructed to be annular. The source trench structure 810 and the gate trench structure 820 are arranged spaced apart from each other and alternately. The bridge trench structure 830 is connected between two adjacent gate trench structures 820, passes through the source trench structure 810 between two adjacent gate trench structures 820, and cuts the source trench structure 810 into a plurality of arc-shaped source trench sections 810a. The arc-shaped source trench sections 810a are constructed to be arc-shaped, and an end of each of the arc-shaped source trench sections 810a is spaced apart from the bridge trench structure 830.

Two or more bridge trench structures 830 are arranged between two adjacent gate trench structures 820, and the bridge trench structures 830 in an inner ring and an outer ring adjacent to each other are staggered with respect to each other. In one or more embodiments, two bridge trench structures 830 are arranged between two adjacent gate trench structures 820, and the bridge trench structures 830 in an inner ring and an outer ring adjacent to each other are staggered with respect to each other by 90 degrees.

The bridge trench structure 830 is further provided in the gate trench structure 820 of an innermost ring, and the bridge trench structure 830 extends in a diameter direction of the gate trench structure 820 of the innermost ring and both ends thereof are connected to the gate trench structure 820 of the innermost ring. Meanwhile, the bridge trench structure 830 cuts the source trench structure 810 of the innermost ring into arc-shaped source trench sections 810a.

The source trench structure 810 includes a first conductor 811 and a first dielectric layer surrounding the first conductor 811. The first dielectric layer 812 isolates the first conductor 811 from the epitaxial layer 801. The gate trench structure 820 includes a second conductor 821 and a second dielectric layer 822 surrounding the second conductor 821, and the second dielectric layer 822 isolates the second conductor 821 from the epitaxial layer 801. The bridge trench structure 830 includes a third conductor 831 and a third dielectric layer 832 surrounding the third conductor 831. The third dielectric layer 832 isolates the third conductor 831 from the epitaxial layer 801.

The trench semiconductor power device layout 80 further includes a peripheral trench structure 840. The peripheral trench structure 840 is constructed to be annular and surrounds the source trench structure 810 and the gate trench structure 820.

The embodiments in accordance with the present disclosure, as described above, neither describe all details thoroughly nor limit the present disclosure, and are only the specific embodiments. Apparently, many modifications and variations are possible in light of the above description. These embodiments are selected and specifically described in this description to better explain the principle and practical application of the present disclosure, so that those skilled in the art may make good use of the present disclosure and modifications based on the present disclosure. The present disclosure is to be limited only by the claims and their full scope and equivalents.

What is claimed is:

1. A trench semiconductor power device, comprising:
a substrate of a first dopant type;
an epitaxial layer of the first dopant type, located on a first surface of the substrate;
a source trench structure that is inside the epitaxial layer and is annular;
a gate trench structure that is inside the epitaxial layer and is annular, wherein the source trench structure and the gate trench structure are spaced apart from each other and alternately arranged;
a bridge trench structure inside the epitaxial layer, wherein the bridge trench structure is connected between two adjacent gate trench structures, passes through the source trench structure between two adjacent gate trench structures, and cuts the source trench structure into a plurality of arc-shaped source trench sections, and an end of each of the arc-shaped source trench sections is spaced apart from the bridge trench structure;
a base region of a second dopant type, arranged between the source trench structure and the gate trench structure adjacent to each other, wherein the second dopant type is opposite to the first dopant type;
a source region of the first dopant type, arranged in the base region;
a gate metal layer, connected to the gate trench structure; and
a source metal layer, connected to the source trench structure and the source region, wherein the source metal layer and the gate metal layer are spaced apart from each other.

2. The trench semiconductor power device according to claim 1, wherein two or more bridge trench structures are arranged between two adjacent gate trench structures.

3. The trench semiconductor power device according to claim 1, wherein the bridge trench structures in an inner ring and an outer ring adjacent to each other are staggered with respect to each other.

4. The trench semiconductor power device according to claim 1, further comprising a peripheral trench structure, wherein the peripheral trench structure surrounds the source trench structure and the gate trench structure, and the peripheral trench structure is connected to the source metal layer.

5. The trench semiconductor power device according to claim 1, wherein the source trench structure comprises a first trench extending from a surface of the epitaxial layer into the epitaxial layer, a first dielectric layer covering a bottom and a sidewall of the first trench, and a first conductor arranged in the first trench;
the gate trench structure comprises a second trench extending from the surface of the epitaxial layer into the epitaxial layer, a second dielectric layer covering a bottom and a sidewall of the second trench, and a second conductor arranged in the second trench; and
the bridge trench structure comprises a third trench extending from the surface of the epitaxial layer into the epitaxial layer, a third dielectric layer covering a bottom and a sidewall of the third trench, and a third conductor arranged in the third trench.

6. The trench semiconductor power device according to claim 5, wherein a depth of the second trench and a depth of the third trench are less than or equal to one-third of a depth of the first trench.

7. The trench semiconductor power device according to claim 5, wherein the second trench has a same depth as the third trench, the second dielectric layer has a same thickness as the third dielectric layer, and the second conductor is connected to the third conductor.

8. The trench semiconductor power device according to claim 5, wherein a thickness of the first dielectric layer is greater than a thickness of the second dielectric layer and a thickness of the third dielectric layer.

9. The trench semiconductor power device according to claim 1, wherein a thickness of a second dielectric layer located at a bottom of a second trench is greater than a thickness of a second dielectric layer located at a sidewall of the second trench, and a thickness of a third dielectric layer located at a bottom of a third trench is greater than a thickness of a third dielectric layer located at a sidewall of the third trench.

10. A trench semiconductor power device layout, comprising:
a source trench structure that is annular;
a gate trench structure that is annular, wherein the source trench structure and the gate trench structure are spaced apart from each other and alternately arranged; and
a bridge trench structure that is connected between two adjacent gate trench structures, passes through the source trench structure between two adjacent gate trench structures, and cuts the source trench structure into a plurality of arc-shaped source trench sections, wherein an end of each of the arc-shaped source trench sections is spaced apart from the bridge trench structure.

11. The trench semiconductor power device layout according to claim 10, wherein two or more bridge trench structures are arranged between two adjacent gate trench structures.

12. The trench semiconductor power device layout according to claim 10, wherein the bridge trench structures in an inner ring and an outer ring adjacent to each other are staggered with respect to each other.

13. The trench semiconductor power device layout according to claim 10, further comprising a peripheral trench structure, wherein the peripheral trench structure surrounds the source trench structure and the gate trench structure.

14. The trench semiconductor power device layout according to claim 10, wherein the source trench structure comprises a first conductor and a first dielectric layer surrounding the first conductor;
the gate trench structure comprises a second conductor and a second dielectric layer surrounding the second conductor; and
the bridge trench structure comprises a third conductor and a third dielectric layer surrounding the third conductor.
